(19) United States
(12) Patent Application Publication
(10) Pub. No.: US 2025/0157996 A1
(43) Pub. Date: May 15, 2025

(54) SEMICONDUCTOR PACKAGES

(71) Applicant: Samsung Electronics Co., Ltd., Suwon-si (KR)

(72) Inventors: Hyunsoo Chung, Suwon-si (KR); Chiwoo Lee, Suwon-si (KR)

(21) Appl. No.: 18/814,848

(22) Filed: Aug. 26, 2024

(30) Foreign Application Priority Data
Nov. 13, 2023 (KR) 10-2023-0156692

(51) Int. Cl. H01L 25/10; H01L 23/00; H01L 23/15; H01L 23/31; H01L 23/538

(52) U.S. Cl. CPC H01L 25/105; H01L 24/08; H01L 24/24; H01L 23/15; H01L 23/3107; H01L 23/5383; H01L 24/16; H01L 24/32; H01L 24/73; H01L 2224/08225; H01L 2224/16227; H01L 2224/24146; H01L 2224/245; H01L 2224/32225; H01L 2224/73204; H01L 2225/1058

(57) ABSTRACT

A semiconductor package includes an interposer substrate including an inorganic material; a first redistribution layer (RDL) on the interposer substrate; a first redistribution structure in the first RDL; a first bonding layer on the first RDL; a first bonding pad in the first bonding layer; a second bonding layer on the first bonding layer; a second bonding pad in the second bonding layer, wherein the second bonding pad contacts the first bonding pad; first semiconductor chips on the second bonding layer, wherein the first semiconductor chips are spaced apart from each other in a horizontal direction; a second RDL on the first semiconductor chips; a second redistribution structure in the second RDL; and second semiconductor chips on the second RDL, wherein the second semiconductor chips are spaced apart from each other in the horizontal direction, and wherein the second semiconductor chips are electrically connected to the second redistribution structure.

### CROSS-REFERENCE TO RELATED APPLICATIONS

This application claims priority under 35 U.S.C. § 119 to Korean Patent Application No. 10-2023-0156692, filed on Nov. 13, 2023 in the Korean Intellectual Property Office (KIPO), the contents of which are herein incorporated by reference in their entirety.

### BACKGROUND OF THE INVENTION

### 1. Field of the Invention

Example embodiments relate to semiconductor packages. More particularly, example embodiments relate to semiconductor packages including a plurality of stacked chips.

### 2. Description of the Related Art

In a fan out wafer level package (FOWLP) technique, conductive posts may be used to electrically connect a lower redistribution layer (RDL) on which a first semiconductor chip is mounted and an upper RDL on which a second semiconductor chip is mounted. If heights of upper surfaces of the conductive posts increase, height distribution (e.g., height variation) may increase, and process difficulty and process cost for forming the conductive posts may increase.

### SUMMARY OF THE INVENTION

Example embodiments may provide semiconductor packages having improved (e.g., enhanced) electrical characteristics.

According to example embodiments, there is provided a semiconductor package. The semiconductor package may include an interposer substrate including an inorganic material; a first redistribution layer (RDL) on the interposer substrate; a first redistribution structure in the first RDL; a first bonding layer on the first RDL; a first bonding pad in the first bonding layer; a second bonding layer on the first bonding layer; a second bonding pad in the second bonding layer, wherein the second bonding pad is in contact with the first bonding pad; first semiconductor chips on the second bonding layer, wherein the first semiconductor chips are spaced apart from each other in a horizontal direction that is parallel with an upper surface of the interposer substrate; a second RDL on the first semiconductor chips; a second redistribution structure in the second RDL; and second semiconductor chips on the second RDL, wherein the second semiconductor chips are spaced apart from each other in the horizontal direction, and wherein the second semiconductor chips are electrically connected to the second redistribution structure.

According to example embodiments, there is provided a semiconductor package. The semiconductor package may include an interposer substrate including an inorganic material; a through electrode in the interposer substrate; a first redistribution layer (RDL) on the interposer substrate; first semiconductor chips on the first RDL, wherein the first semiconductor chips are spaced apart from each other in a horizontal direction that is parallel with an upper surface of the interposer substrate, and the first semiconductor chips are in contact with the first RDL; a second RDL on the first semiconductor chips, wherein the second RDL includes an organic material; and second semiconductor chips on the second RDL, wherein the second semiconductor chips are spaced apart from each other in the horizontal direction, and wherein the second semiconductor chips are in contact with the second RDL.

According to example embodiments, there is provided a semiconductor package. The semiconductor package may include a first interposer substrate including an inorganic material; a first through electrode in the first interposer substrate; a first conductive connection member on a lower surface of the first interposer substrate, wherein the first conductive connection member is electrically connected to the first through electrode; a first redistribution layer (RDL) on the first interposer substrate; a first redistribution structure in the first RDL; a first bonding layer on the first RDL; a first bonding pad in the first bonding layer; a second bonding layer on the first bonding layer; a second bonding pad in the second bonding layer, wherein the second bonding pad is in contact with the first bonding pad; first semiconductor chips on the second bonding layer, wherein the first semiconductor chips are spaced apart from each other in a horizontal direction that is parallel with an upper surface of the first interposer substrate; a second conductive connection member on the first bonding layer, wherein the second conductive connection member extends in a vertical direction that is perpendicular to the upper surface of the first interposer substrate; a first molding member on the first bonding layer, wherein the first molding member is on sidewalls of the second bonding layer, the first semiconductor chips, and the second conductive connection member; a second RDL on the first semiconductor chips, the second conductive connection member, and the first molding member; a second redistribution structure in the second RDL, wherein the second redistribution structure is in contact with the second conductive connection member; a first adhesion layer on the second RDL; a third conductive connection member in the first adhesion layer; second semiconductor chips on the first adhesion layer, wherein the second semiconductor chips are spaced apart from each other in the horizontal direction, and the second semiconductor chips are electrically connected to the third conductive connection member; and a second molding member on the second RDL, wherein the second molding member is on sidewalls of the first adhesion layer and the second semiconductor chips.

In the semiconductor package in accordance with example embodiments, the interposer substrate including an inorganic material having a relatively high hardness (e.g., higher hardness than that of an organic material) may be disposed under and support the semiconductor chips, and thus the semiconductor package may not be warped (may be less warped) even if the semiconductor chips are heavy. Accordingly, the semiconductor package may have improved (e.g., enhanced) stability and electrical characteristic.

### BRIEF DESCRIPTION OF THE DRAWINGS

FIG. 1 is a cross-sectional view illustrating a first semiconductor package in accordance with example embodiments.

FIGS. 2 to 8 are cross-sectional views illustrating a method of manufacturing the first semiconductor package in accordance with example embodiments.

FIG. 9 is a cross-sectional view illustrating a second semiconductor package in accordance with example embodiments.

FIG. 10 is a cross-sectional view illustrating a third semiconductor package in accordance with example embodiments.

FIG. 11 is a cross-sectional view illustrating an electronic device in accordance with example embodiments.

### DETAILED DESCRIPTION OF THE INVENTION

Hereinafter, example embodiments will be explained in detail with reference to the accompanying drawings. Hereinafter, a direction (substantially) parallel to an upper surface of a wafer, a substrate, and/or an interposer may be referred to as a horizontal direction, and a direction (substantially) perpendicular to the upper surface of the wafer, the substrate, and/or the interposer may be referred to as a vertical direction. As used herein, the term “and/or” includes any and all combinations of one or more of the associated listed items.

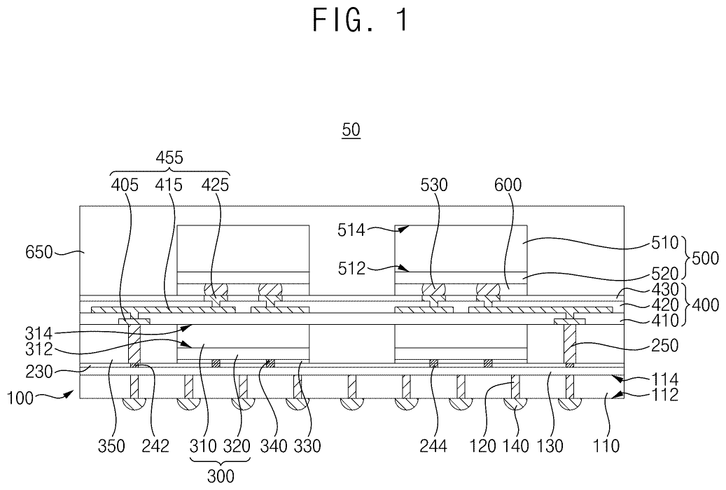

FIG. 1 is a cross-sectional view illustrating a first semiconductor package in accordance with example embodiments.

Referring to FIG. 1, a first semiconductor package 50 may include first and second bonding layers 230 and 330, a first semiconductor chip 300, a second redistribution layer (RDL) 400, a third conductive connection member 530, and a second semiconductor chip 500 sequentially stacked on a first interposer 100 in the vertical direction.

The first semiconductor package 50 may further include first and second conductive connection members 140 and 250, a first adhesion layer 600, and first and second molding members 350 and 650.

The first interposer 100 may include a first interposer substrate 110 having first and second surfaces 112 and 114 opposite to each other in the vertical direction, and a first RDL 130 on the second surface 114 of the first interposer substrate 110. The first surface 112 may be referred to as a lower surface of the first interposer substrate 110, and the second surface 114 may be referred to as an upper surface of the first interposer substrate 110.

In example embodiments, the first interposer substrate 110 may include an inorganic material. The inorganic material may include, for example, an inorganic semiconductor material, such as silicon, germanium, silicon-germanium, gallium, etc., and/or glass.

A plurality of through electrodes 120, each of which may extend in (e.g., extend through) the first interposer substrate 110 in the vertical direction, may be spaced apart from each other in the horizontal direction in the first interposer substrate 110. Each of the through electrodes 120 may include, for example, a metal, such as a copper, aluminum, etc., or a metal nitride, such as titanium nitride, tantalum nitride, etc.

In example embodiments, the first RDL 130 may include insulating interlayers stacked on the first interposer substrate 110 in the vertical direction and a first redistribution structure in the insulating interlayers, and the first redistribution structure may include, for example, wirings, vias, contact plugs, conductive pads, etc. Each of the through electrodes 120 may contact a corresponding portion of the first redistribution structure, such as the conductive pad, to be electrically connected thereto. It will be understood that when an element or layer is referred to as being “connected to”, “coupled to”, “responsive to”, “on”, or “in contact with” another element or layer, it may be directly on, connected to, coupled to, or in contact with the other element or layer, or one or more intervening elements or layers may be present. In contrast, when an element is referred to as being “directly coupled”, “directly connected”, “directly responsive to”, “directly on”, or “directly in contact with” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

In example embodiments, each of the insulating interlayers may include, for example, an oxide, such as silicon oxide, or a low-k dielectric material. The low-k dielectric material may mean a material having a lower dielectric coefficient than that of silicon oxide.

The first conductive connection member 140 may be disposed beneath (on) the first surface 112 of the first interposer substrate 110 and may contact a lower surface of the through electrode 120. In example embodiments, a plurality of first conductive connection members 140 may be spaced apart from each other in the horizontal direction.

Each of the first conductive connection members 140 may include, for example, a conductive bump, which may include a metal such as copper, aluminum, nickel, etc., or solder that includes, for example, an alloy of tin, silver, copper, lead, etc. Spatially relative terms, such as “beneath”, “below”, “lower”, “under”, “above”, “upper”, and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

The first bonding layer 230 may be disposed on and contact an upper surface of the first RDL 130 of the first interposer 100 and may contain first and second conductive pads 242 and 244 therein. A plurality of first conductive pads 242 and a plurality of second conductive pads 244 may be spaced apart from each other in the horizontal direction. In example embodiments, the second conductive pads 244 may be disposed at a central portion of the first bonding layer 230 (compared to the whereabouts of the first conductive pads 242) in a plan view, and the first conductive pads 242 may be disposed at an edge portion of the first bonding layer 230 (compared to the whereabouts of the second conductive pads 244) in a plan view.

The first bonding layer 230 may include an insulating material, for example, silicon carbonitride, silicon nitride, silicon oxide, etc., and each of the first and second conductive pads 242 and 244 may include, for example, a metal, such as copper, aluminum, nickel, etc.

The second conductive connection member 250 may be disposed on the first bonding layer 230, and may contact an upper surface of the first conductive pad 242. The second conductive connection member 250 may have a shape of a pillar extending in the vertical direction, and may include, for example, a metal, such as copper.

The second conductive connection member 250 may be electrically connected to the first conductive pad 242 in the first bonding layer 230, the first redistribution structure in the first RDL 130 of the first interposer 100, the through electrode 120 extending in (e.g., extending through) the first interposer substrate 110, and the first conductive connection member 140. The first conductive connection member 140 may be mounted on a package substrate, for example, a printed circuit board (PCB), a mother board, etc., to be electrically connected thereto.

In example embodiments, the first semiconductor chip 300 may be bonded with the first interposer 100 by a hybrid copper bonding (HCB) method. Particularly, the first semiconductor chip 300 may be mounted on the first bonding layer 230 on the first interposer 100 (e.g., on the first RDL 130), and the second bonding layer 330 containing a third conductive pad 340 therein may be interposed between the first semiconductor chip 300 and the first bonding layer 230. The third conductive pad 340 may contact an upper surface of the second conductive pad 244 in the first bonding layer 230 to be bonded thereto. Thus, the second and third conductive pads 244 and 340 may also be referred to as second and third bonding pads, respectively.

In example embodiments, a single third conductive pad 340 may be formed in the second bonding layer 330, or a plurality of third conductive pads 340 may be spaced apart from each other in the horizontal direction in the second bonding layer 330.

The second bonding layer 330 may include an insulating material, such as silicon carbonitride, silicon nitride, silicon oxide, etc., and the third conductive pad 340 may include, for example, a metal, such as copper, aluminum, nickel, etc.

In example embodiments, the first semiconductor chip 300 may include a first substrate 310 having first and second surfaces 312 and 314 opposite to each other in the vertical direction, and a first insulating interlayer 320 beneath the first surface 312 of the first substrate 310. For example, the first insulating interlayer 320 may be between the first substrate 310 and the second bonding layer 330. The first surface 312 of the first substrate 310 may be referred to as a lower surface of the first substrate 310, and the second surface 314 of the first substrate 310 may be referred to as an upper surface of the first substrate 310.

The first substrate 310 may include a semiconductor material, such as silicon, germanium, silicon-germanium, or a III-V group compound semiconductor, such as GaP, GaAs, GaSb, etc. In example embodiments, the first substrate 310 may be a silicon-on-insulator (SOI) substrate or a germanium-on-insulator (GOI) substrate.

In example embodiments, no through electrode may be formed in the first substrate 310.

A circuit device, such as a memory device, may be formed in the first insulating interlayer 320. The memory device may include a volatile memory device such as a DRAM device, an SRAM device, etc., or a non-volatile memory device such as a flash memory device, an EEPROM device, etc. The circuit device may include circuit patterns, such as transistors, capacitors, wiring structures, etc., and the wiring structures may include, for example, wirings, vias, contact plugs, conductive pads, etc.

In example embodiments, a plurality of first semiconductor chips 300 may be spaced apart from each other in the horizontal direction on the first bonding layer 230 (and/or on the second bonding layer 330). FIG. 1 shows two first semiconductor chips 300, however, the inventive concept is not limited thereto.

The first semiconductor chip 300 may be electrically connected to the second and third conductive pads 244 and 340 in the first and second bonding layers 230 and 330, respectively, the first redistribution structure in the first RDL 130 of the first interposer 100, the through electrode 120 extending in (e.g., extending through) the first interposer substrate 110, and the first conductive connection member 140.

The first molding member 350 may be formed on the first bonding layer 230, and may be on (e.g., cover, extend around, or overlap in the horizontal direction with) the first semiconductor chip 300, the second bonding layer 330, and the second conductive connection member 250. The first molding member 350 may include, for example, a polymer, such as epoxy molding compound (EMC).

The second RDL 400 may be disposed on the first molding member 350, the second conductive connection member 250, and the first semiconductor chip 300.

In an example embodiment, the second RDL 400 may include first, second, and third insulation layers 410, 420, and 430 sequentially stacked in the vertical direction, and a second redistribution structure 455 having conductive structures in the first, second, and third insulation layers 410, 420, and 430. However, the inventive concept is not limited thereto, and the second RDL 400 may include less or more than three insulation layers, and the second redistribution structure 455 may have conductive structures at less or more than three levels. Additionally, the layout of the conductive structures of the second redistribution structure 455 may not be limited to those shown in FIG. 1. Herein, a level, a height, or the like may mean a distance from the first surface 112 or the second surface 114 of the first interposer substrate 110 in the vertical direction. For example, when element A is higher than element B, element A is farther than element B from the second surface 114 of the first interposer substrate 110 in the vertical direction.

The second redistribution structure 455 may include a fourth conductive pad 405 and first and second wirings 415 and 425 sequentially stacked in the vertical direction in the second RDL 400. A lower surface of a portion of the first wiring 415 may contact an upper surface of the fourth conductive pad 405, and a lower surface of a portion of the second wiring 425 may contact an upper surface of a portion of the first wiring 415 serving as a fifth conductive pad. A portion of the second wiring 425 may serve as a sixth conductive pad.

The fourth conductive pad 405 may be formed in the first insulation layer 410, and the first insulation layer 410 may be on (e.g., may cover) a sidewall and an upper surface of a portion of the fourth conductive pad 405. A lower surface of the fourth conductive pad 405 may contact an upper surface of the second conductive connection member 250 to be electrically connected thereto. The first wiring 415 may be formed in the second insulation layer 420, and the second insulation layer 420 may be on (e.g., may cover) a sidewall and an upper surface of a portion of the first wiring 415. The first wiring 415 may include a portion that extends in the first insulation layer 410 to contact (e.g., to be (electrically) connected to) the fourth conductive pad 405. The second wiring 425 may be formed in the third insulation layer 430, and the third insulation layer 430 may be on (e.g., may cover) a sidewall of the second wiring 425. The second wiring 425 may include a portion that extends in the second insulation layer 420 to contact (e.g., to be (electrically) connected to) the first wiring 415. An upper surface of the second wiring 425 may be exposed from the third insulation layer 430.

Each of the first, second, and third insulation layers 410, 420, and 430 may include an organic material. The organic material may include, for example, a polymer, such as polyimide. Additionally, each of the fourth conductive pad 405 and the first and second wirings 415 and 425 may include, for example, a metal, such as aluminum, copper, tin, nickel, gold, platinum, etc., or an alloy thereof.

In example embodiments, the second semiconductor chip 500 may be bonded with the second RDL 400 by a thermal compression bonding (TCB) method. Particularly, the third conductive connection member 530 may be interposed between the second semiconductor chip 500 and the second RDL 400 (e.g., the third insulation layer 430), and may electrically connect the second semiconductor chip 500 and the second RDL 400. Additionally, the first adhesion layer 600 may be interposed between the second semiconductor chip 500 and the second RDL 400 (e.g., the third insulation layer 430), and may be on (e.g., cover or overlap in the horizontal direction with) a sidewall of the third conductive connection member 530.

The second semiconductor chip 500 may include a second substrate 510 having first and second surfaces 512 and 514 opposite to each other in the vertical direction, and a second insulating interlayer 520 beneath the first surface 512 of the second substrate 510.

The second substrate 510 may include a semiconductor material, such as silicon, germanium, silicon-germanium, or a III-V group compound semiconductor, such as GaP, GaAs, GaSb, etc. In example embodiments, the second substrate 510 may be a silicon-on-insulator (SOI) substrate or a germanium-on-insulator (GOI) substrate.

In example embodiments, no through electrode may be formed in the second substrate 510.

A circuit device, such as a memory device, may be formed in the second insulating interlayer 520. The memory device may include a volatile memory device such as a DRAM device, an SRAM device, etc., or a non-volatile memory device such as a flash memory device, an EEPROM device, etc. The circuit device may include circuit patterns, such as transistors, capacitors, wiring structures, etc., and the wiring structures may include, for example, wirings, vias, contact plugs, conductive pads, etc.

In an example embodiment, the second semiconductor chip 500 may have (substantially) the same structure and function as the first semiconductor chip 300. Alternatively, the second semiconductor chip 500 may have different structure and function from the first semiconductor chip 300.

In example embodiments, a width in the horizontal direction of the second semiconductor chip 500 may be (substantially) the same as a width in the horizontal direction of the first semiconductor chip 300. However, a thickness in the vertical direction of the second semiconductor chip 500 may be greater than a thickness in the vertical direction of the first semiconductor chip 300.

In example embodiments, a plurality of second semiconductor chips 500 may be spaced apart from each other in the horizontal direction on the second RDL 400. FIG. 1 shows two second semiconductor chips 500, however, the inventive concept is not limited thereto. In example embodiments, the second semiconductor chips 500 may overlap the first semiconductor chips 300, respectively, in the vertical direction, however, the inventive concept is not limited thereto.

The third conductive connection member 530 may be disposed between the second insulating interlayer 520 (e.g., the conductive pad in the second insulating interlayer 520) of the second semiconductor chip 500 and the sixth conductive pad (e.g., a portion of the second wiring 425) of the second redistribution structure 455 in the second RDL 400 and may contact an upper surface of the sixth conductive pad and a lower surface of the conductive pad in the second insulating interlayer 520.

In an example embodiment, the third conductive connection member 530 may include first and second conductive patterns sequentially stacked in the vertical direction, the first conductive pattern may contact the conductive pad in the second insulating interlayer 520, and the second conductive pattern may contact the sixth conductive pad of the second redistribution structure 455.

The first conductive pattern may include, for example, a metal, such as copper, aluminum, tungsten, nickel, molybdenum, gold, silver, chromium, tin, titanium, etc., and the second conductive pattern may include, for example, tin, tin/silver, tin/copper, tin/indium, tin/silver/copper, etc.

The first adhesion layer 600 may (at least partially) fill a space between the second semiconductor chip 500 and the second RDL 400, and may be on (e.g., cover or overlap in the horizontal direction with) a sidewall of the third conductive connection member 530. The first adhesion layer 600 may include, for example, a non-conductive film (NCF), such as a thermosetting resin.

The second semiconductor chip 500 may be electrically connected to the third conductive connection member 530, the second redistribution structure 455 in the second RDL 400, the second conductive connection member 250, the first conductive pad 242 in the first bonding layer 230, the first redistribution structure in the first RDL 130 of the first interposer 100, the through electrode 120 extending in (e.g., extending through) the first interposer substrate 110, and the first conductive connection member 140.

The second molding member 650 may be formed on the second RDL 400, and may be on (e.g., cover) an upper surface and a sidewall of the second semiconductor chip 500 and a sidewall of the first adhesion layer 600. The second molding member 650 may include, for example, a polymer, such as EMC.

The first semiconductor package 50 may include the first interposer 100 that may be disposed under and support the first semiconductor chips 300, and the first interposer 100 may include the first interposer substrate 110 that includes an inorganic material having a hardness greater (e.g., higher) than that of an organic material. If an RDL including an organic material having a relatively low hardness (e.g., lower or less hardness than that of an inorganic material) is disposed under the first semiconductor chips 300, the RDL may be warped by the first semiconductor chips 300 and the second semiconductor chips 500 sequentially stacked thereon in the vertical direction.

However, in example embodiments, the first interposer 100 may be disposed under the first semiconductor chips 300, and the first interposer 100 may include the first interposer substrate 110 and the first RDL 130, which include (e.g., each of which includes) an inorganic material having a relatively high hardness (e.g., a higher or a greater hardness than a hardness of an organic material), and thus the first interposer 100 may not be warped even if the first and second semiconductor chips 300 and 500 are heavy. For example, the warpage of the first interposer 100 may be reduced (e.g., prevented) by an inorganic material, which has a greater hardness than that of an organic material, in the first interposer substrate 110 and/or the first RDL 130. Accordingly, the first semiconductor package 50 including the first interposer 100 may have improved (e.g., enhanced) stability and electrical characteristic.

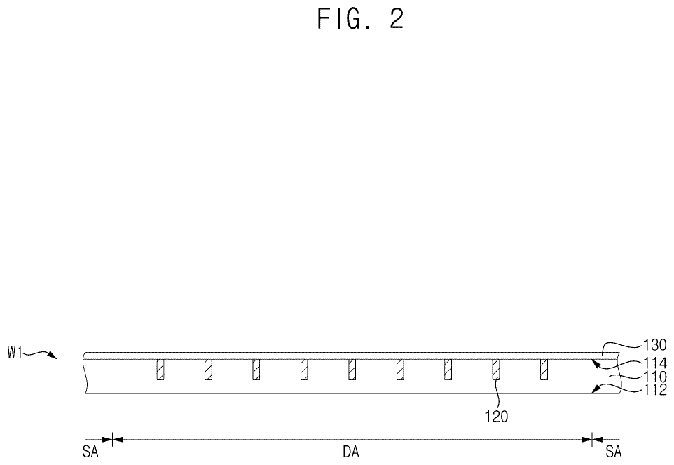

FIGS. 2 to 8 are cross-sectional views illustrating a method of manufacturing the first semiconductor package in accordance with example embodiments.

Referring to FIG. 2, a first wafer W1 may be provided.

In example embodiments, the first wafer W1 may include a first interposer substrate 110 having first and second surfaces 112 and 114 opposite to each other in the vertical direction, and the first interposer substrate 110 may include an inorganic material, such as an inorganic semiconductor material (e.g., silicon, germanium, silicon-germanium, gallium, etc.) or glass.

Additionally, the first wafer W1 may include a plurality of die regions DA and a scribe lane region SA adjacent (e.g., extending around or surrounding) (each of) the plurality of die regions DA, and the first wafer W1 may be cut by a sawing process along the scribe lane region SA to be individual first interposers in respective die regions DA (e.g., the first interposer 100 in FIG. 1).

In the die region DA, a plurality of through electrodes 120, each of which may extend in the vertical direction through an upper portion of the first interposer substrate 110, that is, a portion of the first interposer substrate 110 adjacent to the second surface 114. The plurality of through electrodes 120 may be spaced apart from each other in the horizontal direction.

A first RDL 130 may be formed on the second surface 114 of the first interposer substrate 110. In example embodiments, the first RDL 130 may include insulating interlayers stacked in the vertical direction and a first redistribution structure in the insulating interlayers, and the first redistribution structure may include, for example, wirings, vias, contact plugs, and conductive pads. Each of the through electrodes 120 may contact a portion of the first redistribution structure, such as the conductive pad to be electrically connected thereto.

In example embodiments, the first RDL 130 may be formed on the first interposer substrate 110 by a back end of line (BEOL) process.

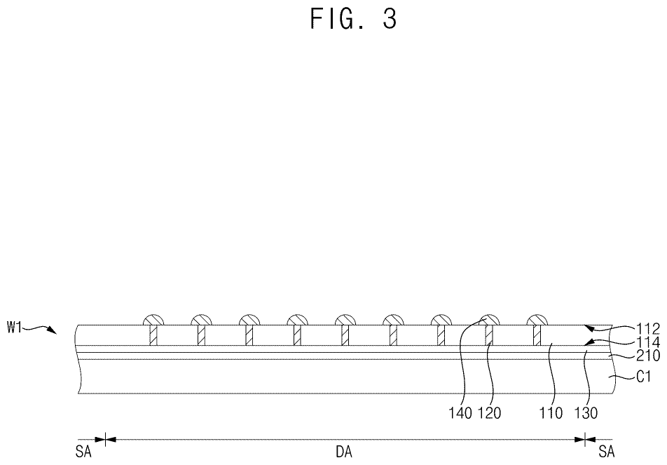

Referring to FIG. 3, a first temporary adhesion layer 210 may be formed on (e.g., attached to) a first carrier substrate C1, the first carrier substrate C1 may be bonded with the first wafer W1 such that the first temporary adhesion layer 210 may contact an upper surface of the first RDL 130, and a structure including the first carrier substrate C1 and the first wafer W1 may be overturned.

The first carrier substrate C1 may include, for example, a metal or non-metal plate, a silicon substrate, a glass substrate, etc. The first temporary adhesion layer 210 may include a material that may lose adhesion by irradiation of light or heat treatment. In an example embodiment, the first temporary adhesion layer 210 may include a release tape.

A portion of the first wafer W1 adjacent to the first surface 112 may be removed by, e.g., a grinding process to expose an upper surface of the through electrode 120, and a first conductive connection member 140 may be formed on the first wafer W1 to contact the upper surface of the through electrode 120. A plurality of first conductive connection members 140 may be spaced apart from each other in the horizontal direction, and each of the first conductive connection members 140 may include, for example, a conductive bump or conductive ball.

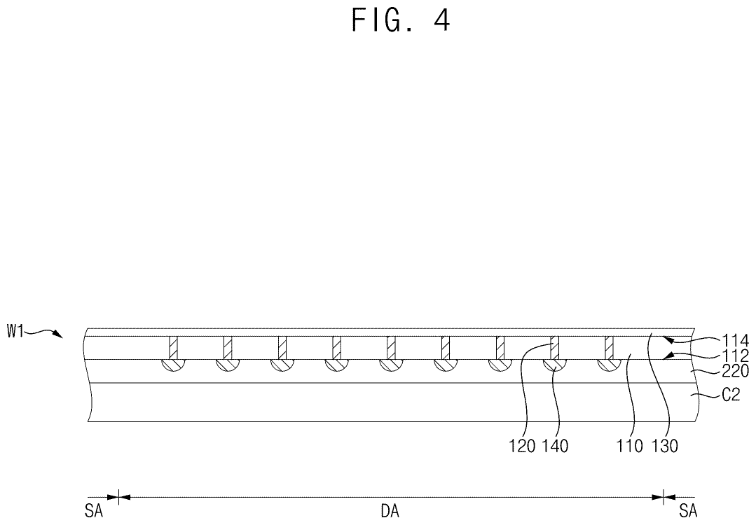

Referring to FIG. 4, a second temporary adhesion layer 220 may be formed on (e.g., attached to) a second carrier substrate C2, the second carrier substrate C2 may be bonded with the first wafer W1 such that the second temporary adhesion layer 220 may contact the first surface 112 of the first interposer substrate 110 to be on (e.g., to cover or overlap with) the first conductive connection member 140, and a structure including the first carrier substrate C1, the second carrier substrate C2, and the first wafer W1 may be overturned.

The second carrier substrate C2 may include, for example, a metal or non-metal plate, a silicon substrate, a glass substrate, etc. The second temporary adhesion layer 220 may include a material that may lose adhesion by irradiation of light or heat treatment. In an example embodiment, the second temporary adhesion layer 220 may include glue.

The first temporary adhesion layer 210 bonded with the first wafer W1 may be divided from the first RDL 130, so that the first carrier substrate C1 may be divided away from the first wafer W1, and that the upper surface of the first RDL 130 may be exposed.

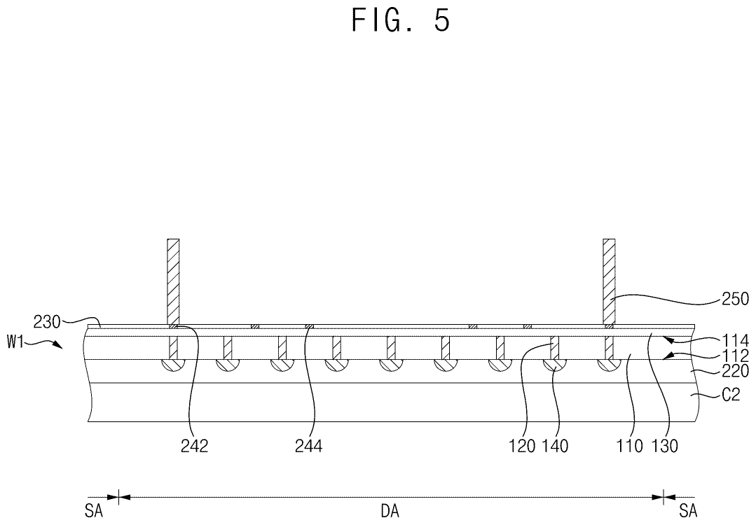

Referring to FIG. 5, a first bonding layer 230 containing first and second conductive pads 242 and 244 therein may be formed on the exposed upper surface of the first RDL 130.

In example embodiments, the first bonding layer 230 may be formed by a deposition process, such as a chemical vapor deposition (CVD) process, an atomic layer deposition (ALD) process, etc., and each of the first and second conductive pads 242 and 244 may extend in (e.g., extend through) the first bonding layer 230. The first and second conductive pads 242 and 244 may be spaced apart from each other in the horizontal direction in the first bonding layer 230.

A first photoresist layer may be formed on the first bonding layer 230 and the first and second conductive pads 242 and 244, an exposure process and a developing process may be performed on the first photoresist layer to form a first photoresist pattern having a first opening exposing an upper surface of the first conductive pad 242, and forming a second conductive connection member 250 in the first opening by an electroplating process or an electroless plating process.

In example embodiments, the second conductive connection member 250 may have a shape of a pillar extending in the vertical direction, and may contact the upper surface of the first conductive pad 242.

The first photoresist pattern may be removed by, e.g., an ashing process and/or a stripping process.

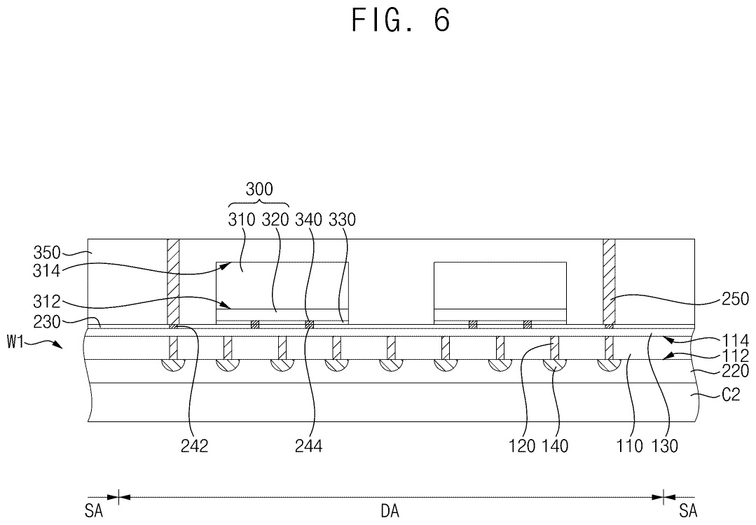

Referring to FIG. 6, a first semiconductor chip 300 may be mounted on the first wafer W1, and may be bonded with the first wafer W1 by an HCB method.

In example embodiments, the first semiconductor chip 300 may include a first substrate 310 having first and second surfaces 312 and 314 opposite to each other in the vertical direction and a first insulating interlayer 320 on the first surface 312 of the first substrate 310.

The first semiconductor chip 300 may be bonded with the first wafer W1 by the HCB method, as follows.

A second bonding layer 330 containing a third conductive pad 340 therein, which may contact the conductive pad in the first insulating interlayer 320, may be formed on the first insulating interlayer 320, and the first semiconductor chip 300 may be bonded with the first wafer W1 such that the second bonding layer 330 may contact the first bonding layer 230 on the first wafer W1. The third conductive pad 340 in the second bonding layer 330 may contact the second conductive pad 244 in the first bonding layer 230.

Alternatively, the first semiconductor chip 300 may be bonded with the first wafer W1 by a TCB method. However, a thickness in the vertical direction of the semiconductor package including the first semiconductor chip 300 bonded with the first wafer W1 by the HCB method may be less than a thickness in the vertical direction of the semiconductor package including the first semiconductor chip 300 bonded with the first wafer W1 by the TCB.

A first molding member 350 may be formed on the first bonding layer 230 to be on (e.g., to cover or overlap with) the first semiconductor chip 300 and the second conductive connection member 250, and a planarization process may be performed on the first molding member 350 until an upper surface of the second conductive connection member 250 is exposed. The planarization process may include, for example, a chemical mechanical polishing (CMP) process.

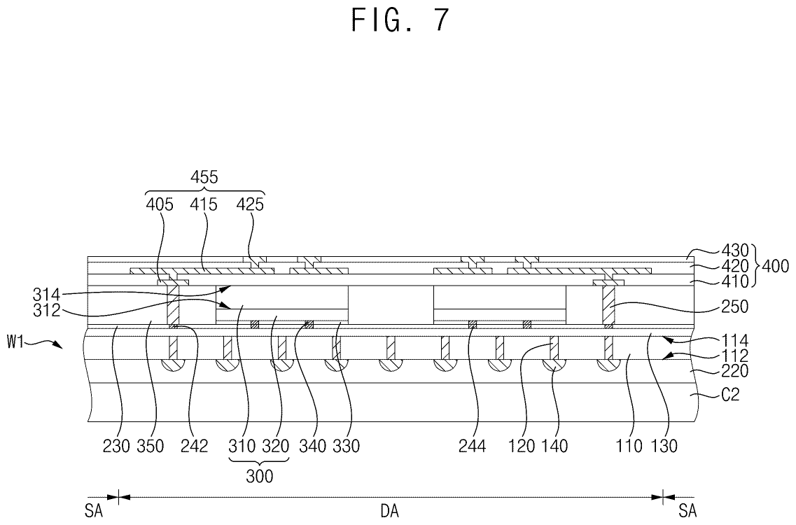

Referring to FIG. 7, upper portions of the first molding member 350, the second conductive connection member 250, and the first semiconductor chip 300 may be removed by a CMP process or a grinding process, so that vertical thicknesses of the first molding member 350, the second conductive connection member 250, and the first semiconductor chip 300 may decrease.

A second RDL 400 may be formed on the first molding member 350, the second conductive connection member 250, and the first semiconductor chip 300.

In an example embodiment, the second RDL 400 may include first, second, and third insulation layers 410, 420, and 430 sequentially stacked in the vertical direction and a second redistribution structure 455 including conductive structures in the first, second, and third insulation layers 410, 420, and 430.

For example, the second RDL 400 may be formed by following processes.

A fourth conductive pad 405 may be formed on the first molding member 350 to contact the upper surface of the second conductive connection member 250, the first insulation layer 410 may be formed on the first molding member 350 and the first semiconductor chip 300 to be on (e.g., to cover or overlap with) the fourth conductive pad 405, and the first insulation layer 410 may be partially removed to form a second opening exposing an upper surface of the fourth conductive pad 405.

A first seed layer may be formed on an upper surface of the first insulation layer 410, a sidewall of the second opening and the exposed upper surface of the fourth conductive pad 405 by the second opening, an electroplating process or an electroless plating process may be performed to form a first wiring layer on the first seed layer, the first wiring layer may be patterned to form a first wiring 415, and a portion of the first seed layer not covered by the first wiring 415 may be removed. The first wiring 415 may contact the upper surface of the fourth conductive pad 405 through the second opening. A portion of the first wiring 415 may serve as a fifth conductive pad.

A second insulation layer 420 may be formed on the first insulation layer 410 to be on (e.g., to cover or overlap with) the first wiring 415, the second insulation layer 420 may be partially removed to form a third opening exposing an upper surface of the first wiring 415, a second seed layer may be formed on an upper surface of the second insulation layer 420, a sidewall of the third opening and the exposed upper surface of the first wiring 415 by the third opening, a second wiring layer may be formed on the second seed layer by an electroplating process or an electroless plating process, the second wiring layer may be patterned to form a second wiring 425, and a portion of the second seed layer not covered by the second wiring 425 may be removed. The second wiring 425 may contact the upper surface of the first wiring 415 through the third opening.

A third insulation layer 430 may be formed on the second insulation layer 420 to be on (e.g., to cover or overlap with) the second wiring 425, and a planarization process may be performed on the third insulation layer 430 until an upper surface of the second wiring 425 is exposed. Thus, the third insulation layer 430 may cover (or overlap in the horizontal direction with) a sidewall of the second wiring 425. A portion of the second wiring 425 may serve as a sixth conductive pad.

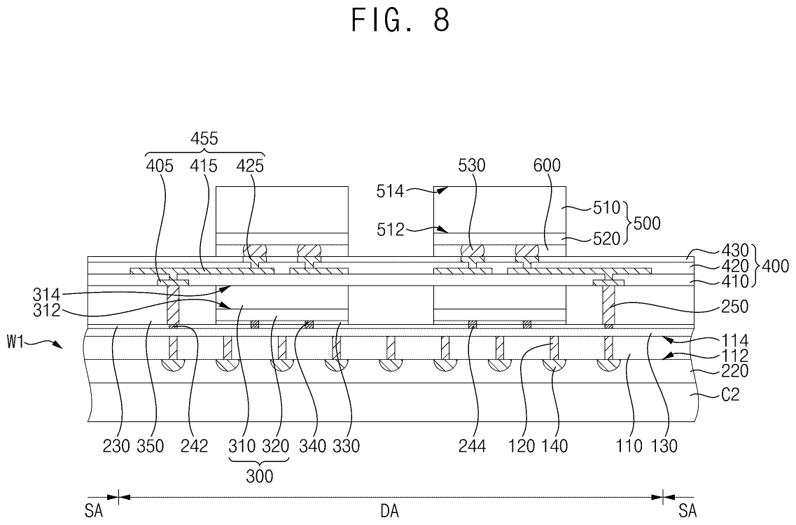

Referring to FIG. 8, a second semiconductor chip 500 may be mounted on the second RDL 400, and may be bonded with the second RDL 400 by a TCB method.

In example embodiments, the second semiconductor chip 500 may include a second substrate 510 that has first and second surfaces 512 and 514 opposite to each other in the vertical direction and a second insulating interlayer 520 on the first surface 512 of the second substrate 510.

In an example embodiment, the second semiconductor chip 500 may have (substantially) the same structure and function as the first semiconductor chip 300. In some embodiments, the second semiconductor chip 500 may have different structure and function from the first semiconductor chip 300.

The second semiconductor chip 500 may be bonded with the second RDL 400, as follows.

A third seed layer may be formed on the second insulating interlayer 520 and the conductive pad of the second semiconductor chip 500, a second photoresist pattern having a fourth opening overlapping the conductive pad in the vertical direction may be formed on the third seed layer, an electroplating process or an electroless plating process may be performed to form a first conductive pattern on a portion of the third seed layer in the fifth opening, the second photoresist pattern may be removed by, e.g., an ashing process and/or a stripping process to expose a portion of the third seed layer, and the exposed portion of the third seed layer may be removed.

A third photoresist layer may be formed on the second insulating interlayer 520 to be on (e.g., to cover or to overlap with) the first conductive pattern, the third photoresist layer may be patterned to form a third photoresist pattern having a sixth opening exposing an upper surface of the first conductive pattern, an electroplating process or an electroless plating process may be performed to form a preliminary second conductive pattern in the sixth opening, the third photoresist pattern may be removed, and a reflow process may be performed to transform the preliminary second conductive pattern into a second conductive pattern.

Thus, a third conductive connection member 530 including the first and second conductive patterns stacked in the vertical direction may be formed.

A first adhesion layer 600 may be formed on the second insulating interlayer 520 to be on (e.g., to cover or overlap in the horizontal direction with) the third conductive connection member 530, the second semiconductor chip 500 may be overturned so that the second surface 514 of the second semiconductor chip 500 may face upwardly, and the second semiconductor chip 500 may be mounted on the second RDL 400 such that the first adhesion layer 600 attached to the second semiconductor chip 500 may contact an upper surface of the second RDL 400. The first adhesion layer 600 may include, for example, an NCF such as thermosetting resin.

The second semiconductor chip 500 may be bonded with the second RDL 400 by a thermal compression process at a temperature of equal to or less than (about) 400° C. In the thermal compression process, the NCF of the first adhesion layer 600 may be melted to have fluidity, and may flow between each of the second semiconductor chips 500 and the second RDL 400. The NCF may flow and be cured between the second semiconductor chip 500 and the second RDL 400, and may fill a space between the second semiconductor chip 500 and the second RDL 400. A portion of the cured first adhesion layer 600 may protrude in the horizontal direction from a sidewall of the second semiconductor chip 500.

By the thermal compression process, the third conductive connection member 530 may be bonded with the sixth conductive pad in the second RDL 400.

In example embodiments, a plurality of second semiconductor chips 500 spaced apart from each other in the horizontal direction may be mounted on and bonded with the second RDL 400. In example embodiments, the second semiconductor chips 500 on the second RDL 400 may overlap (in the vertical direction) corresponding ones of the first semiconductor chips 300, respectively.

Referring to FIG. 1, a second molding member 650 may be formed on the second RDL 400 to be on (e.g., to cover or overlap with) the second semiconductor chips 500 and the first adhesion layers 600.

The first wafer W1 may be cut by a sawing process along the scribe lane region SA to form a plurality of individual first interposers 100.

During the sawing process, the first and second molding members 350 and 650 stacked in the vertical direction may also be cut, and may be formed (e.g., divided) on the individual first interposer 100 to cover (e.g., to overlap in the horizontal direction with) sidewalls of the first and second semiconductor chips 300 and 500, respectively.

By the above processes, the first semiconductor package 50 may be manufactured.

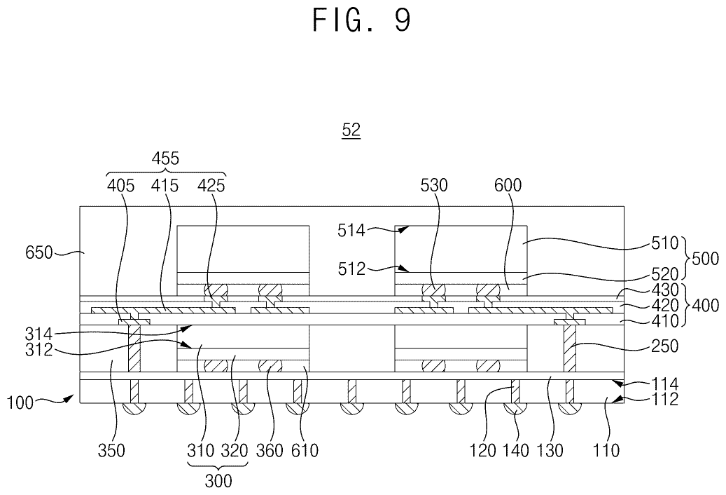

FIG. 9 is a cross-sectional view illustrating a second semiconductor package in accordance with example embodiments. The second semiconductor package may be substantially the same as or similar to the first semiconductor package 50 described in FIG. 1 except for some elements, and thus repeated explanations may be omitted herein.

Referring to FIG. 9, the first semiconductor chip 300 of a second semiconductor package 52 may be bonded with the first interposer 100 by a TCB method.

Thus, the second semiconductor package 52 may not include the first and second bonding layers 230 and 330 and the second and third conductive pads 244 and 340 in FIG. 1 but may include a fourth conductive connection member 360 and a second adhesion layer 610.

Thus, the fourth conductive connection member 360 may contact a lower surface of the conductive pad in the first insulating interlayer 320 and an upper surface of the conductive pad in the first RDL 130 of the first interposer 100 to be electrically connected thereto.

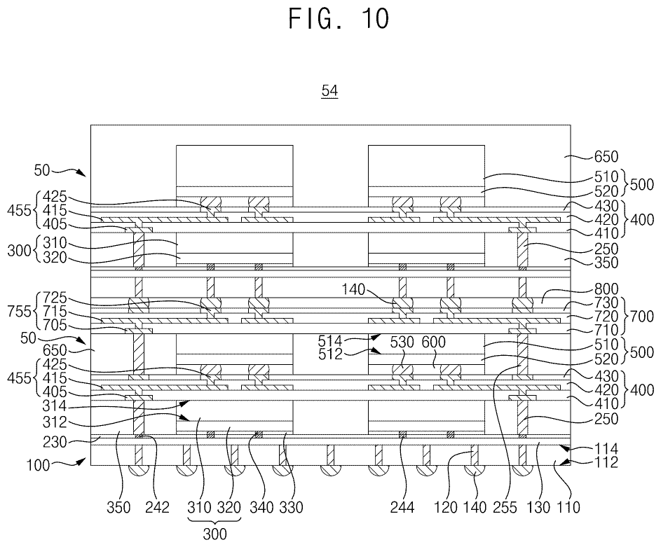

FIG. 10 is a cross-sectional view illustrating a third semiconductor package in accordance with example embodiments. The third semiconductor package may be (substantially) the same as or similar to the first semiconductor package 50 described in FIG. 1 except for some elements, and thus repeated explanations may be omitted herein.

Referring to FIG. 10, the third semiconductor package 54 may have a stacked structure in which the first semiconductor packages 50 shown in FIG. 1 are stacked in the vertical direction.

However, in a lower one of the first semiconductor packages 50, a fifth conductive connection member 255 may be further formed in the second molding member 650 to contact an upper surface of the sixth conductive pad (e.g., a portion of the second wiring 425) in the second RDL 400. A vertical thickness of each of the second semiconductor chips 500 may be (substantially) the same as or similar to that of the first semiconductor chip 300. Additionally, the second molding member 650 may not be on (e.g., may not cover or overlap in the vertical direction with) an upper surface of the second semiconductor chip 500, and may be on (e.g., may cover or overlap in the horizontal direction with) a sidewall of the second semiconductor chip 500.

A third RDL 700 may be formed between the first semiconductor packages 50, and a third adhesion layer 800 may be formed between the third RDL 700 and an upper one of the first semiconductor packages 50 to be on (e.g., cover or overlap in the horizontal direction with) a sidewall of the first conductive connection member 140 included in the upper one of first semiconductor packages 50.

The third RDL 700 may include fourth, fifth, and sixth insulation layers 710, 720, and 730 stacked in the vertical direction and a third redistribution structure 755 including conductive structures in the fourth, fifth, and sixth insulation layers 710, 720, and 730. The third redistribution structure 755 may include a seventh conductive pad 705 and third and fourth wirings 715 and 725 sequentially stacked in the vertical direction.

The first and second semiconductor chips 300 and 500 included in the upper one of the first semiconductor packages 50 may be electrically connected to the fifth conductive connection member 255 included in the lower one of the first semiconductor packages 50 through the first conductive connection member 140 in the upper one of the first semiconductor packages 50 and the third redistribution structure 755.

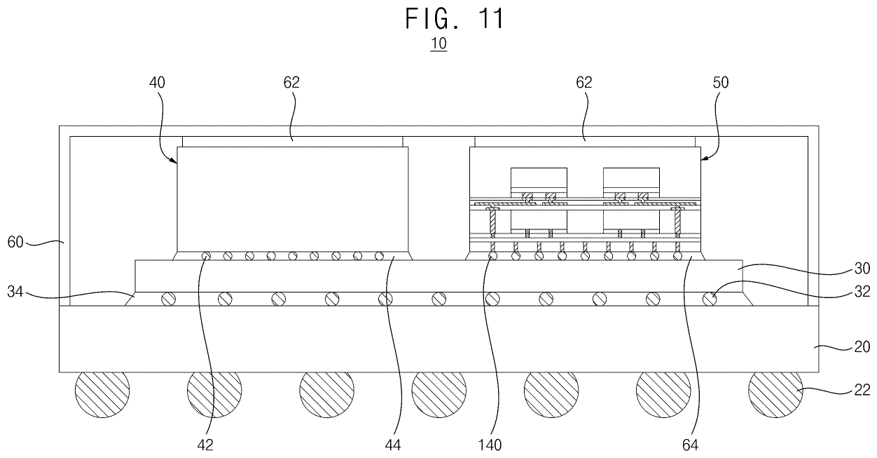

FIG. 11 is a cross-sectional view illustrating an electronic device in accordance with example embodiments.

This electronic device may include the first semiconductor package 50 shown in FIG. 1 as a second semiconductor device 50, however, the inventive concept is not limited thereto and may include the second semiconductor package 52 shown in FIG. 9 or the third semiconductor package 54 shown in FIG. 10, as the second semiconductor device 50.

Referring to FIG. 11, an electronic device 10 may include a package substrate 20, a second interposer 30, a first semiconductor device 40 and the second semiconductor device 50. The electronic device 10 may further include first, second, and third underfill members 34, 44, and 64, a heat slug 60 and a heat dissipation member 62.

In example embodiments, the electronic device 10 may be a memory module having a 2.5D package structure, and thus may include the second interposer 30 for electrically connecting the first and second semiconductor devices 40 and 50 to each other.

In example embodiments, the first semiconductor device 40 may include a logic device, and the second semiconductor device 50 may include a memory device. The logic device may be an application-specific integrated circuit (ASIC) chip including, for example, a central processing unit (CPU), a graphics processing unit (GPU), a micro-processor, a micro-controller, an application processor (AP), a digital signal processing core, etc. The memory device may be the first semiconductor package 50 of FIG. 1.

In example embodiments, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The second interposer 30 may be mounted on the package substrate 20 through a seventh conductive connection member 32. In example embodiments, a planar area of the second interposer 30 may be smaller than a planar area of the package substrate 20. The second interposer 30 may be disposed within an area of the package substrate 20 in a plan view.

The second interposer 30 may be, for example, a silicon interposer or a redistribution interposer having a plurality of wirings therein. The first semiconductor device 40 and the second semiconductor device 50 may be connected (e.g., electrically connected) to each other through the wirings in the second interposer 30 or electrically connected to the package substrate 20 through the seventh conductive connection member 32. The seventh conductive connection member 32 may include, for example, a micro-bump. The second interposer 30 (e.g., a silicon interposer) may provide a high-density interconnection between the first and second semiconductor devices 40 and 50.

The first semiconductor device 40 may be disposed on the second interposer 30. The first semiconductor device 40 may be mounted on and bonded with the second interposer 30 by a TCB method. In this case, the first semiconductor device 40 may be mounted on the second interposer 30 such that an active surface on which conductive pads are formed may face downwardly toward the second interposer 30. The conductive pads of the first semiconductor device 40 may be electrically connected to conductive pads of the second interposer 30 through an eighth conductive connection member 42. For example, the eighth conductive connection member 42 may include, for example, a micro-bump.

In some embodiments, the first semiconductor device 40 may be mounted on the second interposer 30 by a wire bonding method, and in this case, the active surface of the first semiconductor device 40 may face upwardly.

The second semiconductor device 50 may be disposed on the second interposer 30, and may be spaced apart from the first semiconductor device 40 in the horizontal direction. The second semiconductor device 50 may be mounted on and bonded with the second interposer 30 by a TCB method. In this case, conductive pads of the second semiconductor device 50 may be electrically connected to conductive pads of the second interposer 30 by the first conductive connection member 140.

Although a single first semiconductor device 40 and a single second semiconductor device 50 are disposed on the second interposer 30, however, the inventive concept is not limited thereto, and a plurality of first semiconductor devices 40 and/or a plurality of second conductive devices 50 may be disposed on the second interposer 30.

In example embodiments, the first underfill member 34 may (at least partially) fill a space between the second interposer 30 and the package substrate 20, and the second and third underfill members 44 and 64 may (at least partially) fill a space between the first semiconductor device 40 and the second interposer 30 and a space between the second semiconductor device 50 and the second interposer 30, respectively.

The first, second, and third underfill members 34, 44, and 64 may include a material having a relatively high fluidity to effectively fill a small space between the first and second semiconductor devices 40 and 50 and the second interposer 30 and a small space between the second interposer 30 and the package substrate 20. For example, each of the first, second, and third underfill members 34, 44, and 64 may include an adhesive containing an epoxy material.

In example embodiments, the heat slug 60 may be on (e.g., cover or overlap in the vertical direction) the package substrate 20 to thermally contact the first and second semiconductor devices 40 and 50. That is, heat may be transferred from the first and second semiconductor devices 40 and 50 to the heat slug 60 through the package substrate 20. The heat dissipation member 62 may be disposed on an upper surface of each of the first and second semiconductor devices 40 and 50, and may include, for example, thermal interface material (TIM). The heat slug 60 may thermally contact the first and second semiconductor devices 40 and 50 via the heat dissipation member 62. That is, heat may be transferred from the first and second semiconductor devices 40 and 50 to the heat slug 60 through the heat dissipation member 62.

A conductive pad may be formed at a lower portion of the package substrate 20, and a sixth conductive connection member 22 may be disposed beneath the conductive pad. In example embodiments, a plurality of sixth conductive connection members 22 may be spaced apart from each other in the horizontal direction. The sixth conductive connection member 22 may be, for example, a solder ball. The electronic device 10 may be mounted on a module board via the sixth conductive connection members 22 to form a memory module.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package comprising:
an interposer substrate including an inorganic material;
a first redistribution layer (RDL) on the interposer substrate;
a first redistribution structure in the first RDL;
a first bonding layer on the first RDL;
a first bonding pad in the first bonding layer;
a second bonding layer on the first bonding layer;
a second bonding pad in the second bonding layer, wherein the second bonding pad is in contact with the first bonding pad;
first semiconductor chips on the second bonding layer, wherein the first semiconductor chips are spaced apart from each other in a horizontal direction that is parallel with an upper surface of the interposer substrate;
a second RDL on the first semiconductor chips;
a second redistribution structure in the second RDL; and
second semiconductor chips on the second RDL, wherein the second semiconductor chips are spaced apart from each other in the horizontal direction, and
wherein the second semiconductor chips are electrically connected to the second redistribution structure.

2. The semiconductor package of claim 1, wherein the inorganic material includes silicon, germanium, silicon-germanium, and/or gallium.

3. The semiconductor package of claim 1, wherein the inorganic material includes glass.

4. The semiconductor package of claim 1, wherein the second RDL includes an organic material.

5. The semiconductor package of claim 4, wherein the organic material includes a polymer.

6. The semiconductor package of claim 1, wherein each of the first bonding layer and the second bonding layer includes silicon carbonitride, silicon nitride, and/or silicon oxide, and
wherein each of the first bonding pad and second bonding pad includes copper.

7. The semiconductor package of claim 1, wherein the first RDL includes silicon oxide and/or a low-k dielectric material.

8. The semiconductor package of claim 1, further comprising:
a first molding member on the first bonding layer, wherein the first molding member is on a sidewall of the second bonding layer and sidewalls of the first semiconductor chips; and
a second molding member on the second RDL, wherein the second molding member is on sidewalls of the second semiconductor chips.

9. The semiconductor package of claim 8, wherein the first molding member and the second molding member are separated from each other by the second RDL.

10. The semiconductor package of claim 8, wherein the second molding member is on upper surfaces of the second semiconductor chips.

11. The semiconductor package of claim 1, wherein a thickness of each of the second semiconductor chips in a vertical direction that is perpendicular to the upper surface of the interposer substrate is greater than a thickness of each of the first semiconductor chips in the vertical direction.

12. The semiconductor package of claim 1, wherein a width of each of the second semiconductor chips in the horizontal direction is equal to a width of each of the first semiconductor chips in the horizontal direction, and
wherein the second semiconductor chips overlap the first semiconductor chips, respectively in a vertical direction that is perpendicular to the upper surface of the interposer substrate.

13. The semiconductor package of claim 1, further comprising:
a conductive connection member on the first bonding layer, wherein the conductive connection member extends in a vertical direction that is perpendicular to the upper surface of the interposer substrate, and
wherein the conductive connection member is in contact with a portion of the second redistribution structure.

14. The semiconductor package of claim 1, wherein the interposer substrate includes a through electrode therein, and
wherein each of the first semiconductor chips and the second semiconductor chips is free of having the through electrode therein.

15. A semiconductor package comprising:
an interposer substrate including an inorganic material;
a through electrode in the interposer substrate;
a first redistribution layer (RDL) on the interposer substrate;
first semiconductor chips on the first RDL, wherein the first semiconductor chips are spaced apart from each other in a horizontal direction that is parallel with an upper surface of the interposer substrate, and the first semiconductor chips are in contact with the first RDL;
a second RDL on the first semiconductor chips, wherein the second RDL includes an organic material; and
second semiconductor chips on the second RDL, wherein the second semiconductor chips are spaced apart from each other in the horizontal direction, and
wherein the second semiconductor chips are in contact with the second RDL.

16. The semiconductor package of claim 15, further comprising:
a conductive connection member between the first RDL and the second RDL;
a first redistribution structure in the first RDL; and
a second redistribution structure in the second RDL,
wherein the conductive connection member extends in a vertical direction that is perpendicular to the upper surface of the interposer substrate, and
wherein the conductive connection member is in contact with the first redistribution structure and the second redistribution structure.

17. The semiconductor package of claim 16, wherein each of the second semiconductor chips is electrically connected to the first redistribution structure through the second redistribution structure and the conductive connection member.

18. The semiconductor package of claim 15, wherein the inorganic material includes silicon, and the organic material includes a polymer.

19. A semiconductor package comprising:
a first interposer substrate including an inorganic material;
a first through electrode in the first interposer substrate;
a first conductive connection member on a lower surface of the first interposer substrate, wherein the first conductive connection member is electrically connected to the first through electrode;
a first redistribution layer (RDL) on the first interposer substrate;
a first redistribution structure in the first RDL;
a first bonding layer on the first RDL;
a first bonding pad in the first bonding layer;
a second bonding layer on the first bonding layer;
a second bonding pad in the second bonding layer, wherein the second bonding pad is in contact with the first bonding pad;
first semiconductor chips on the second bonding layer, wherein the first semiconductor chips are spaced apart from each other in a horizontal direction that is parallel with an upper surface of the first interposer substrate;
a second conductive connection member on the first bonding layer, wherein the second conductive connection member extends in a vertical direction that is perpendicular to the upper surface of the first interposer substrate;
a first molding member on the first bonding layer, wherein the first molding member is on sidewalls of the second bonding layer, the first semiconductor chips, and the second conductive connection member;
a second RDL on the first semiconductor chips, the second conductive connection member, and the first molding member;
a second redistribution structure in the second RDL, wherein the second redistribution structure is in contact with the second conductive connection member;
a first adhesion layer on the second RDL;
a third conductive connection member in the first adhesion layer;
second semiconductor chips on the first adhesion layer, wherein the second semiconductor chips are spaced apart from each other in the horizontal direction, and the second semiconductor chips are electrically connected to the third conductive connection member; and
a second molding member on the second RDL, wherein the second molding member is on sidewalls of the first adhesion layer and the second semiconductor chips.

20. The semiconductor package of claim 19, further comprising:
a fourth conductive connection member in the second molding member, wherein the fourth conductive connection member is electrically connected to the second redistribution structure;
a third RDL on the second semiconductor chips, the second molding member, and the fourth conductive connection member;
a third redistribution structure in the third RDL, wherein the third redistribution structure is in contact with the fourth conductive connection member;
a second adhesion layer on the third RDL;
a fifth conductive connection member in the second adhesion layer, wherein the fifth conductive connection member is in contact with the third redistribution structure;
a second interposer substrate on the second adhesion layer, wherein the second interposer substrate includes a second inorganic material;
a second through electrode in the second interposer substrate, wherein the second through electrode is in contact with the fifth conductive connection member;
a fourth RDL on the second interposer substrate;
a fourth redistribution structure in the fourth RDL;
a third bonding layer on the fourth RDL;
a third bonding pad in the third bonding layer;
a fourth bonding layer on the third bonding layer;
a fourth bonding pad in the fourth bonding layer, wherein the fourth bonding pad is in contact with the third bonding pad;
third semiconductor chips on the fourth bonding layer, wherein the third semiconductor chips are spaced apart from each other in the horizontal direction;
a sixth conductive connection member on the third bonding layer, wherein the sixth conductive connection member extends in the vertical direction;
a third molding member on the third bonding layer, wherein the third molding member is on sidewalls of the fourth bonding layer, the third semiconductor chips, and the sixth conductive connection member;
a fifth RDL on the third semiconductor chips, the sixth conductive connection member, and the third molding member;
a fifth redistribution structure in the fifth RDL, wherein the fifth redistribution structure is in contact with the sixth conductive connection member;
a third adhesion layer on the fifth RDL;
a seventh conductive connection member in the third adhesion layer;
fourth semiconductor chips on the third adhesion layer, wherein the fourth semiconductor chips are spaced apart from each other in the horizontal direction, and the fourth semiconductor chips are electrically connected to the seventh conductive connection member; and
a fourth molding member on the fifth RDL, wherein the fourth molding member is on sidewalls of the third adhesion layer and the fourth semiconductor chips.
